(19) United States
(12) Patent Application Publication
(10) Pub. No.: US 2017/0154965 A1
(43) Pub. Date: Jun. 1, 2017

(54) Semiconductor Device

(71) Applicant: Infineon Technologies Austria AG, Villach (AT)

(72) Inventors: Ralf Siemieniec, Villach (AT); Oliver Blank, Villach (AT); Marion Hoja, Villach (AT); Christoph Kadow, Gauting (DE); Sabine Konrad, Villach (AT); Cedric Ouvrard, Villach (AT)

(21) Appl. No.: 15/361,249

(22) Filed: Nov. 25, 2016

(30) Foreign Application Priority Data
Nov. 27, 2015 (DE) 102015120675.7

(51) Int. Cl. H01L 29/417; H01L 29/739; H01L 29/06; H01L 29/78

(52) U.S. Cl. CPC H01L 29/41741; H01L 29/7813; H01L 29/7397; H01L 29/41708; H01L 29/41766; H01L 29/0696

(57) ABSTRACT

A semiconductor device includes a semiconductor substrate including, between a bottom side and a top side, a first trench and a second trench extending in a vertical direction, and a contact groove arranged between the first trench and the second trench. The contact groove has a longitudinal extension in a plane perpendicular to the vertical direction. The longitudinal extension of the contact groove at least partially has a wave-shape.

### TECHNICAL FIELD

Embodiments described herein relate to a semiconductor device having a contact groove structure, and specifically relate to a power semiconductor device having a contact groove structure.

### BACKGROUND

Current semiconductor devices such as MOSFETs are widely used as electronic switches for switching electrical loads. Semiconductor devices having a high block voltage can be formed with mesa regions between respective two adjacent gate trenches. The mesa regions typically include source regions which are contacted by respective contact regions. To avoid parasitic effect, a good ohmic connection to the source regions is needed.

In view of the above, there is a need for new semiconductor devices having an improved avalanche strength. Specifically, there is a need for new power semiconductor devices having a high block voltage and a high avalanche strength while the occurrence of cavities in the source metal at or near the contact groove can be minimized or even avoided.

### SUMMARY

According to an aspect of the present disclosure, a semiconductor device is provided. The semiconductor device includes a semiconductor substrate having, between a bottom side and a top side of the semiconductor substrate from the top side in a vertical direction, a source region of a first conductivity type, a body region of a second conductivity type, and a drift region of the first conductivity type. The semiconductor substrate further includes at least a first trench and a second trench extending from the top side at least partially into the drift region, wherein the body region is arranged between the first trench and the second trench, and a contact groove extending from the top side at least partially into the body region and arranged between the first trench and the second trench, wherein the contact groove has a longitudinal extension in a plane perpendicular to the vertical direction, and wherein the longitudinal extension of the contact groove at least partially has a wave-shape. The semiconductor device further includes a first main electrode arranged on the top side of the semiconductor substrate and a body contact provided at least partially within the contact groove and configured for contacting at least the first main electrode and the body region.

According to another aspect of the present disclosure, a semiconductor device is provided. The semiconductor device includes a semiconductor substrate, having between a bottom side and a top side of the semiconductor substrate from the top side in a vertical direction, a source region of a first conductivity type, a body region of a second conductivity type, and a drift region of the first conductivity type. The semiconductor substrate further includes at least a first trench and a second trench each extending from the top side at least partially into the drift region, wherein the first trench and the second trench extend parallel to each other in a first lateral direction, and wherein the body region is arranged between the first trench and the second trench, and at least one contact groove extending from the top side at least partially into the body region, wherein the at least one contact groove comprises portions having a first extension in the first lateral direction and a second extension in a second lateral direction perpendicular to the first lateral direction, wherein the second extension is larger than the first extension. The semiconductor device further includes a first main electrode arranged on the top side of the semiconductor substrate and a body contact provided at least partially within the at least one contact groove and configured for contacting at least the first main electrode and the body region.

According to yet another aspect of the present disclosure, a semiconductor device is provided. The semiconductor device includes a semiconductor substrate having a bottom side and a top side, at least a first trench and a second trench each extending from the top side into the semiconductor substrate, wherein the first trench and the second trench extend parallel to each other in a first lateral direction, at least one semiconductor mesa region arranged between the first trench and the second trench and extending to the top side, the at least one semiconductor mesa region being bound by the first trench and the second trench on opposite sides of the semiconductor mesa region, at least one contact groove formed at the top side of the semiconductor substrate and extending into the semiconductor mesa region, wherein the first trench and the second trench extend from the top side of the semiconductor substrate deeper into the semiconductor substrate than the at least one contact groove, wherein the at least one contact groove includes portions having a first extension in the first lateral direction and a second extension in a second lateral direction perpendicular to the first lateral direction, and wherein the second extension is larger than the first extension.

Those skilled in the art will recognize additional features and advantages upon reading the following detailed description, and upon viewing the accompanying drawings.

### BRIEF DESCRIPTION OF THE DRAWINGS

The components in the figures are not necessarily to scale, instead emphasis being placed upon illustrating the principles of the invention. Moreover, in the figures, like reference numerals designate corresponding parts. In the drawings:

FIG. 1 shows a cross-sectional view of a semiconductor device according to embodiments described herein;

FIG. 2 shows a schematic plan view of a semiconductor substrate having trenches and contact grooves according to embodiments described therein;

FIG. 3 shows a section of the semiconductor substrate of FIG. 2;

FIG. 4 shows a schematic plan view of a semiconductor substrate having trenches and contact grooves according to further embodiments described herein;

FIG. 5 shows a section of the semiconductor substrate of FIG. 4;

FIGS. 6A to 6I and 6K to 6N show cross-sectional views of the semiconductor device during manufacturing thereof.

### DETAILED DESCRIPTION

In the following detailed description, reference is made to the accompanying drawings, which form a part hereof, and in which are shown by way of illustration specific embodiments in which the invention may be practiced. In this regard, directional terminology, such as “top”, “bottom”, “front”, “back”, leading”, “trailing”, “lateral”, and “vertical” etc., is used with reference to the orientation of the Figure(s) being described unless otherwise stated. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. The embodiments being described use specific language, which should not be construed as limiting the scope of the appended claims.

The terms “electrical connection” and “electrically connected” describe an ohmic connection between two elements.

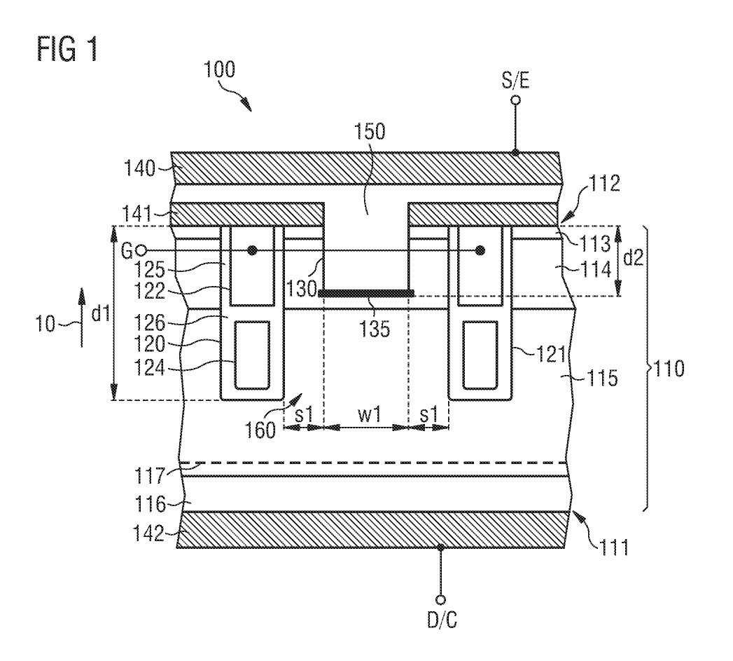

With reference to FIG. 1, a semiconductor device 100 according to an embodiment is described.

In an embodiment, the semiconductor device 100 includes a semiconductor substrate 110 having at least a first trench 120 and a second trench 121 both extending in a vertical direction and being laterally spaced from each other, and a contact groove 130 arranged between the first trench 120 and the second trench 121. The contact groove 130 has a longitudinal extension in a plane perpendicular to the vertical direction 10. The longitudinal extension of the contact groove 130 at least partially has a wave-shape or is formed by separate portions.

A mesa region 160 can be arranged between the first and second trench 120, 121, and can extend to a top side 112 of the semiconductor substrate 110. The contact groove 130 can be arranged in the mesa region 160 at the top side 112. The first and second trench 120, 121 can extend deeper into the semiconductor substrate 110 than the contact groove 130.

The contact groove 130 can include portions which are arranged closer to the first trench 120 than other portions of the contact groove 130 which are arranged more remote from the first trench 120. Furthermore, portions of the contact groove 130 which are arranged closer to the first trench 120 can be arranged more remote from the second trench 121, i.e. at a larger distance to the second trench 121 than to the first trench 120. Other portions of the contact groove 130 which are arranged closer to the second trench 121 can be arranged more remote from the first trench 120, i.e. at a larger distance to the first trench 120 than to the second trench 121.

The contact groove 130 can be filled with a material different than the semiconductor substrate 110 such as a polycrystalline semiconductor material, a metal or metal alloy, a layer stack of metal or metal alloy layers, or a combination thereof.

In a more specific embodiment, the semiconductor device 100 includes a semiconductor substrate 110 which can be made of silicon, silicon carbide, III-V semiconductor material, or any other suitable semiconductor material. The semiconductor substrate 110 can include a single crystal material and at least one epitaxial layer formed thereon. Alternatively, the semiconductor substrate 110 can be formed from a wafer without any additional epitaxial layer or from a wafer formed by bonding two wafers with an optional epitaxial deposition.

The semiconductor substrate 110 includes a bottom side 111 and a top side 112 arranged opposite the bottom side 111. The top side 112 is spaced distant from the bottom side 111 in a vertical direction 10. The semiconductor substrate 110 includes between the top side 112 and the bottom side 111, in this order, a source region 113 of a first conductivity type, a body region 114 of a second conductivity type, and a drift region 115 of the first conductivity type. The semiconductor substrate 110 can include a further semiconductor region 116 arranged at the bottom side 111 that is either of the first conductivity type or of the second conductivity type. As an example, the further semiconductor region 116 can be a drain region or an emitter region.

The first conductivity type is either n-conducting and the second conductivity type is p-conducting, or the first conductivity type is p-conducting and the second conductivity type is n-conducting. In cases where the further semiconductor region 116 and the drift region 115 are of the same conductivity type, the semiconductor device 100 can be a field effect transistor (FET), such as a MOSFET. In other cases where the further semiconductor region 116 and drift region 115 are of different or complementary conductivity type, the semiconductor device 100 can be an IGBT (insulated gate bipolar transistor). Typically, the first conductivity type is n-conducting and the second conductivity type is p-conducting for power devices.

The source region 113 is arranged in the semiconductor substrate 110 at the top side 112, In some embodiments, the source region 113 is highly n-doped. At the bottom side 111, the further semiconductor region 116 is formed in the semiconductor substrate 110. In case of a FET-transistor, the further semiconductor region 116 is a drain region having the same conductivity type as the source region 113. Alternatively, in case of an IGBT the further semiconductor region 116 forms an emitter region which is of opposite conductivity to that of the source region 113. In the following description, the further semiconductor region 116 is referred to as drain region 116 without being limited thereto.

The body region 114 is arranged in the semiconductor substrate 110 in contact with the source region 113. The body region 114 typically has a conductivity type opposite to that of the source region 113 so that a pn-junction is formed between the source region 113 and the body region 114.

The drift region 115 is arranged between the body region 114 and the drain region 116 and typically has the same conductivity type as the source region 113. The doping concentration of the drift region 115 substantially corresponds to the background doping concentration of the semiconductor substrate 110 or of the epitaxial layer if one is used. However, the doping concentration of the drift region 115 can also exhibit a doping profile having a maximum or a minimum at a desired location or an increasing or decreasing doping concentration in the vertical direction 10. The drift region 115 forms with the body region 114 a pn-junction.

An optional field-stop region 117 having the same conductivity as the drift region 115 but being higher doped than the drift region 115 can be arranged between the drift region 115 and the drain region 116.

The semiconductor substrate 110 includes at least a first trench 120 and a second trench 121 extending from the source region 113 at least partially into the drift region 115. The body region 114 is arranged at least between the first trench 120 and the second trench 121. The bottom of the at least one first trench 120 and the bottom of the at least one second trench 121 are spaced from the drain region 116 in the vertical direction 10. The region between the first trench 120 and the second trench 121 can be a semiconductor mesa region 160. Specifically, the semiconductor mesa region 160 can be arranged between the first trench 120 and the second trench 121 and can extend to the top side 112. The semiconductor mesa region 160 can be bound by the first trench 120 and the second trench 121 on opposite sides of the semiconductor mesa region 160.

In the embodiment illustrated in FIG. 1, the first and second trenches 120, 121 have a substantially identical arrangement. Therefore, the following description refers to the first and second trenches 120, 121 equally. Each of the first and second trenches 120, 121 includes a gate electrode 122 and optionally a field electrode 124, with the gate electrode 122 being arranged above the field electrode 124 in proximity to the top side 112. The gate electrodes 122 extend vertically, i.e. parallel to the vertical extension of the first and second trenches 120, 121, from the source region 113 to the drift region 115. Since the body region 114 is arranged between the source region 113 and the drift region 115, the gate electrodes 122 of the first and second trenches 120, 121 can extend completely through the body region 114. Gate electrodes 122 and/or field electrodes 124 can be formed of polysilicon or any other suitable conductive material. According to some embodiments, the first and second trenches 120, 121 can be referred to as “gate trenches”.

Gate dielectric layers 125, sometimes referred to as gate oxide layers (GOX), are arranged between the gate electrodes 122 and the semiconductor substrate 110 and particularly between the gate electrodes 122 and the body region 114. The gate dielectric layers 125 electrically insulated the gate electrodes 122 from the semiconductor substrate 110.

Field dielectric layers 126, typically field oxides (FOX), are arranged between the field electrodes 124 and the semiconductor substrate 110, particularly between the field electrodes 124 and the drift region 115, and insulate the field electrodes 124 from the drift region 115. The field dielectric layers 126 have a significantly greater thickness in comparison with the gate dielectric layers 125 to withstand high electrical field strengths occurring during operation of the semiconductor device 100 and to avoid electrical breakdown between the field electrodes 124 and the drift region 115.

The gate electrodes 122 and field electrodes 124 are different from each other and serve different purposes. The gate electrodes 122 are arranged close to the body region 114 to control the conductivity of respective channel regions which extend from the source region 113 to the drift region 115 along the gate dielectric layers 125. Different thereto, the field electrodes 124 are arranged close to the drift region 115 to influence the distribution of the electrical field in the drift region 115 or to provide compensation charges for depleting the drift region 115 in a blocking state. In some embodiments, some first and second trenches 120, 121 include a gate electrode 122 but no field electrode. In further embodiments, the gate electrodes 122 and the field electrodes 124 are electrically connected.

The first and second trenches 120, 121 can define, together with the mesa region 160, respective separate cells of the semiconductor device 100 which are electrically connected in parallel to each other to increase the available cross-section for the load current and to reduce the on-state resistance. For example, the lateral extension of a cell can be defined to be from the lateral center of the first trench 120 to the lateral center of the second trench 121.

A first main electrode 140 is arranged on the top side 112 of the semiconductor substrate 110. According to some embodiments, the first main electrode 140 is selected from the group consisting of a source electrode and an emitter electrode. A second main electrode 142 is arranged on the bottom side 111 of the semiconductor substrate 110. According to some embodiments, the second main electrode 142 is selected from the group consisting of a drain electrode and a collector electrode. In some implementations, the first main electrode 140 can be referred to as source metallization, and the second main electrode 142 can be referred to as drain metallization, The first main electrode 140 is electrically insulated from the semiconductor substrate 110 by an insulating layer 141 having openings only in regions where contact regions with contact grooves to be described later are formed to allow electrical connection to the source region 113 and the body region 114.

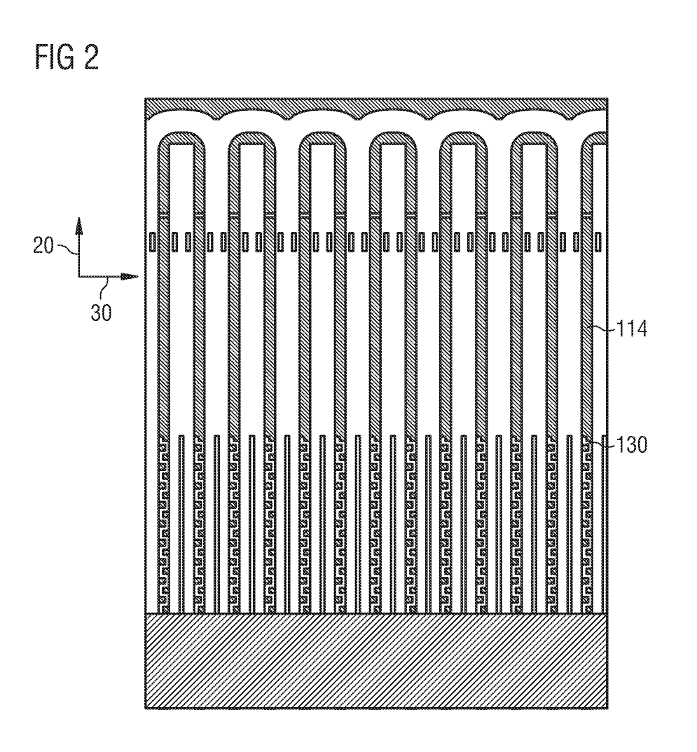

Contact regions are formed in the semiconductor substrate 110 at the top side 112 between adjacent trenches 120, 121. A contact groove 130 extends from the source region 113, i.e. from the top side 112 of the semiconductor substrate 110, at least partially into the body region 114 and is arranged between the first trench 120 and the second trench 121. The contact groove 130 is further described with reference to FIGS. 2 to 5. In some implementations, a body contact region 135 is provided at the bottom of the contact groove 130. The body contact region 135 can have a doping concentration higher than a doping concentration of the body region 114.

A body contact 150 is provided at least partially within the contact groove 130 and configured for contacting at least the first main electrode 140 and the body region 114, Specifically, the body contact 150 is configured for contacting the first main electrode 140, the source region 113 and the body region 114. Further, the body contact 150 can be in contact with the body contact region 135. Typically, the contact groove 130 is filled with a highly conductive material. As an example, the body contact 150 can include, or be made of, at least one material selected from the group consisting of: Al, AlCu, NiAl, W, WTi, Ti, TiN, AlSiCu, doped polysilicon, simple doped polysilicon and any combinations thereof.

According to an embodiment, a silicide portion is formed between the body contact 150 and the body region 114 or the body contact region 135. Silicides reduce the contact resistance between the metallic body contact 150 and the semiconductor substrate 110. For example, NiAl with varying composition can be used to contact a SiC semiconductor substrate 110. W, Ti, and TiN are particularly suitable for Si semiconductor substrates 110.

The body contact 150 can include a metallic liner, such as W, WiTi, Ti, TiN, NiAl, which is provided to form the respective silicide and a bulk conductive material, such as Al, AlCu, AlSiCu, that is formed on the metallic liner and that fills the contact groove 130.

The contact groove 130 has a width w1 in a direction, or first lateral direction, substantially perpendicular to the vertical direction 10. In some embodiments, the width w1 can be in a range of 350 nm to 1200 nm, and specifically in a range of 500 nm to 1000 nm. As an example, the width w1 can be less than (or about) 600 nm.

A high width of the semiconductor mesa region 160 allows for high block voltages of the semiconductor device 100. Specifically, for semiconductor devices having a high block voltage and a corresponding increased width of a mesa region between two adjacent gate trenches, also a width of contact groove provided in the mesa region should be increased. This results from a high avalanche strength, which is required, for instance, when switching inductive loads. The contact groove 130 has the width w1 selected such that the highly doped region, for example, a highly doped p-region (such as the body contact region 135), at the bottom of the contact groove 130 does not extend in the channel region but is still positioned close to the channel region to avoid that a parasitic bipolar transistor latches up. This allows for said high avalanche strength.

Specifically, p+ implantation and activation can be performed in order to provide the body contact region 135 at the bottom of the contact groove 130. The p+ implantation may cause a diffusion of p+ dopants in a lateral direction from a side wall of the contact groove 130, e.g., in a direction towards the channel region. When the p+ dopant diffuses into the channel region, the threshold voltage is increased. Accordingly, a sufficient distance between the diffusion region of the body contact region and the channel region/trench should be kept in order to avoid an increase of the threshold voltage. Assuming an n-channel device, the contact dopant can be B or BF₂. While BF₂ provides a lateral scattering that is not too large, diffusion of the boron is not significantly suppressed. A similar situation can occur in p-channel devices where arsenic or antimony can be used for implantation.

On the other hand, the lateral distance between the contact groove 130 or the body contact region 135 and the first and second trenches 120, 121 should not be too large as this could lead, due to the larger distance, to a larger body resistance which increases the risk that parasitic bipolar transistors latch-up during operation of the semiconductor device.

When forming the contact groove 130, the lateral distance to the first and second trenches 120, 121 could be set accordingly to take account of the above described effects. For example, the contact groove 130 could be formed with a laterally larger width. This, on the other hand, may cause problems with respect to the filling of the contact groove 130 as described further below.

According to an embodiment, the contact groove 130 is formed to have regions with varying lateral distances to each of the first and the second trenches 120, 121. The contact groove 130 can have first regions 130a and second regions 130b. The first regions 130a can be arranged closer to the first trench 120 than the second regions 130b. The second regions 130b can be arranged closer to the second trench 121 than the first regions 130a. Thus, the lateral distance between the first regions 130a and the first trench 120 is less than the lateral distance between the second regions 130b and the first trench 120. The lateral distance between the second regions 130b and the second trench 121 is less than the lateral distance between the first regions 130a and the second trench 121. The first and second regions 130a, 130b are connected with each other by laterally transverse regions 130c.

The first and second regions 130a, 130b can be alternatingly arranged. The first and second regions 130a, 130b can have the same length, or can be of different length.

The contact groove 130 can thus be provided with a reduced width, which is referred to as w3, to avoid the formation of cavities or voids as described below. The alternating arrangement of the first and second regions 130a, 130b allows reduction of the lateral distance between the contact groove 130 and the first and second trenches 120, 121 to prevent that a parasitic bipolar transistor can latch-up. This improves the ruggedness of the device.

According to an embodiment, a body contact region 135 is formed at the bottom of the contact groove 130 and therefore also at the bottom of the first, second and third regions 130a, 130b, 130c so that each of the first, second and third regions 130a, 130b, 130c has respective body contact regions. The lateral outdiffusion of the body contact regions needs to be taken into account when defining the location and width of the first, second and third regions 130a, 130b, 130c.

In some implementations, a distance s1 is provided between a side wall of the first trench 120 and a side wall of the at least one contact groove 130 adjacent to the first trench 120, and between a side wall of the second trench 121 and a side wall of the at least one contact groove 130 adjacent to the second trench 121. The distance s1 can be less than 400 nm, and specifically less than 300 nm. The short distance between both side walls provides for the high avalanche strength. If a body contact region 135 is formed, the distance s1 can also be defined as a distance between a lateral boundary of the above-mentioned diffusion region of the body contact region 135 and the side wall of a respective trench 121, 122.

However, when a source metal (e.g., the source metallization or first main electrode 140) is deposited in the manufacturing of the semiconductor device 100, cavities may occur in the source metal at or near the contact groove 130 due to the increased width of the contact groove 130. The contact groove 130 according to the embodiments described herein has a non-linear or segmented configuration allowing for a high avalanche strength while avoiding the occurrence of cavities in the source metal at or near the contact groove 130 due to the increased width of the contact groove 130. Examples of the contact grooves having the non-linear configuration and the segmented configuration are shown in FIGS. 2 to 5. Such cavities or voids may be formed when the contact groove 130 has an increased width. By forming the contact grooves 130 thin and, at the same time, forming the contact grooves 130 in a wave-shape or meander-shape, the contact groove 130 are “thin” enough (when seen in plane projection onto the top side 112) to avoid cavity formation of the deposited source metal while at the same time the alternating arrangement of the contact groove 130 close to the first and second trenches avoids that parasitic bipolar-transistors can latch-up. Hence, source regions formed in comparably wide mesa regions can be reliably electrically connected.

It is assumed that the cavity formation which may occur in wider contact grooves 130 results from the non-conformal deposition of metal.

According to an embodiment, the lateral width of the contact groove 130, i.e. the shortest distance between opposite sidewalls of the contact groove 130, can be up to 700 nm to avoid cavity formation.

According to an embodiment, the ratio between the lateral width w3 of the contact groove 130 and the lateral width of the mesa region 160 can less than 10, specifically less than 5, and more specifically less than 2 which indicates that comparably thin contact grooves 130 are used for comparably wide mesa regions 160.

The first and second trenches 120, 121 have a depth d1 in the vertical direction 10 and the contact groove 130 has a depth d2 in the vertical direction 10. The depths d1 and d2 can be defined from the top side 112 in a direction, e.g., the vertical direction 10, towards the bottom side 111. According to some embodiments, which can be combined with other embodiments described therein, the depth d2 of the at least one contact groove 130 in the vertical direction 10 is less than the depth d1 of the first and second trenches 120, 121 in the vertical direction 10. As an example, the depth d2 of the contact groove 130 can be less than 50% of the depth d1, specifically less than 30%, and more specifically less than 10%.

The semiconductor device 100 can be made of any semiconductor material suitable for manufacturing semiconductor devices. Examples of such materials include, without being limited thereto, elementary semiconductor materials such as silicon (Si), group IV compound semiconductor materials such as silicon carbide (SiC) or silicon germanium (SiGe), binary, ternary or quaternary III-V semiconductor materials such as gallium arsenide (GaAs), gallium phosphide (GaP), indium phosphide (InP), gallium nitride (GaN), aluminium gallium nitride (AlGaN), indium gallium phosphide (InGaPa) or indium gallium arsenide phosphide (InGaAsP), and binary or ternary II-VI semiconductor materials such as cadmium telluride (CdTe) and mercury cadmium telluride (HgCdTe) to name few. The above mentioned semiconductor materials are also referred to as homojunction semiconductor materials. When combining two different semiconductor materials a heterojunction semiconductor material is formed. Examples of heterojunction semiconductor materials include, without being limited thereto, silicon (SiₓC₁₋ₓ)and SiGe heterojunction semiconductor material. For power semiconductor applications currently mainly Si, SiC and GaN materials are used.

The extent of the above described outdiffusion of the body contact region 135 is different for different semiconductor materials. For example, the outdiffusion is more pronounced in Si than in SiC.

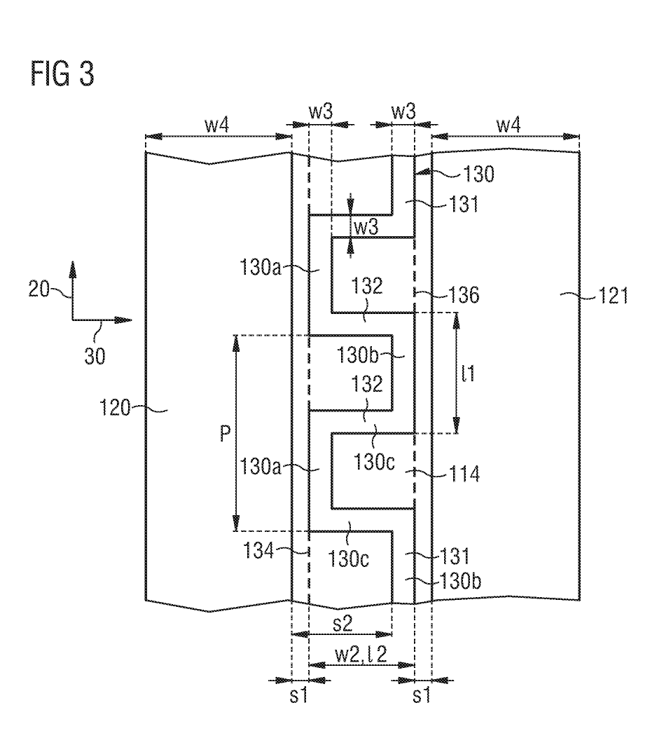

FIG. 2 shows a schematic plan view of a semiconductor substrate having trenches 120, 121 and contact grooves 130 according to embodiments described therein. FIG. 3 shows a section of the semiconductor substrate of FIG. 2.

The trenches 120, 121 can have the longitudinal extension in a first lateral direction which is referred to as first direction 20. The first direction 20 is perpendicular to the vertical direction 10. The trenches 120, 121 can have a width w4 in a second lateral direction 30 perpendicular to the first direction 20 and the vertical direction 10. The second lateral direction 30 is referred to as second direction 30. The first direction 20 and the second direction 30 can span a plane perpendicular to the vertical direction 10. Specifically, the plane can be substantially parallel to the surface of the semiconductor substrate 110 provided by the top side 111.

According to some embodiments, the contact groove 130 has a longitudinal extension in the plane perpendicular to the vertical direction 10, wherein the longitudinal extension of the contact groove 130 at least partially has a wave-shape. The term “wave-shape” as used throughout the present disclosure can be understood in the sense that the contact groove 130 is, in plane projection onto the top side 112, not a straight line. Specifically, the longitudinal extension of the contact groove 130 changes its direction in the plane perpendicular to the vertical direction 10. In some embodiments, the wave-shape of the contact groove 130 is selected from the group consisting of: non-linear, meander-shaped, sinusoidal, triangular, rectangular, and any combination thereof.

In plane projection onto the top side 112, the wave-shape of the contact groove 130 is confined within an area defined by a first boundary 134 at a first side of the contact groove 130 and by a second boundary 136 at a second side of the contact groove 130 opposite the first side. A width w2 of the area in the second direction 30 perpendicular to the longitudinal extension of the trenches 120, 121 is larger than a width w3 of the at least one contact groove 130. The width w2 of the area is the second direction 30 corresponds to a distance between the first boundary 134 and the second boundary 136 in said second direction 30. The width w3 of the at least one contact groove 130 corresponds to distance between two opposite points of the side walls of the contact groove 130, wherein the two opposite points are selected such that a line connecting the two opposite points is perpendicular to the tangents to the two opposite points of the side walls.

According to some embodiments, the width w2 of the area in the direction 30 perpendicular to the longitudinal extension of the first trench 120 and/or the second trench 121 is in a range of 350 nm to 1200 nm, specifically 500 nm to 700 nm, and is more specifically about 600 nm. In some embodiments, the lateral width w3 of the at least one contact groove 130 is in a range of 200 nm to 700 nm, and is more specifically in a range of 300 nm to 600 nm.

In some embodiments, a distance s1 between a side wall of the first trench 120 and the first boundary 134 adjacent to the first trench 120 and a distance s1 between a side wall of the second trench 121 and the second boundary 136 adjacent to the second gate trench 121 is less than 400 nm, and specifically less than 300 nm. The distances s1 with respect to the first boundary 134 and the second boundary 136 can be substantially equal, wherein the term “substantially” shall account for manufacturing tolerances. The distance s1 of FIG. 3 can correspond to the distance s1 shown in FIG. 1.

According to some embodiments, which can be combined with other embodiments described herein, the contact groove 130 has first portions 131 having a first extension l1 and second portions 132 having a second extension l2. The second extension l2 can correspond to the width w1 illustrated in FIG. 1. In some implementations, the first portions 131 and the second portions 132 can extend in directions substantially perpendicular to each other. As an example, the first portions 131 can extend substantially parallel to each other in the first direction 20 parallel to the longitudinal extension of the first trench 120 and/or the second trench 121. The second portions 132 can extend substantially parallel to each other in the second direction 30 substantially perpendicular to the longitudinal extension of the first trench 120 and/or the second trench 121. The first portions 131 and the second portions 132 can define a meander-like or rectangular wave-like shape of the contact groove 130.

In some embodiments, a distance s2 in the second direction 30 between a sidewall of a trench 120, 121 and an adjacent sidewall of a first group of first portions 131 is less than 1000 nm, and specifically less than 500 nm. The first group of first portions 131 can include the first portions 131 that are further away from the side wall of the trench 120, 121 than first portions 131 of a second group of first portions 131. In the example of FIG. 3, when considering the first trench 120, the first group of first portions 131 includes the first portions 131 on the right-hand side, and the second group of first portions 131 includes the first portions 131 on the left-hand side. A sum of the distance s2, the width w3 and the distance s1 is substantially equal to a distance between a sidewall of the first trench 120 and a sidewall of the second trench 121 opposite the sidewall of the first trench 120.

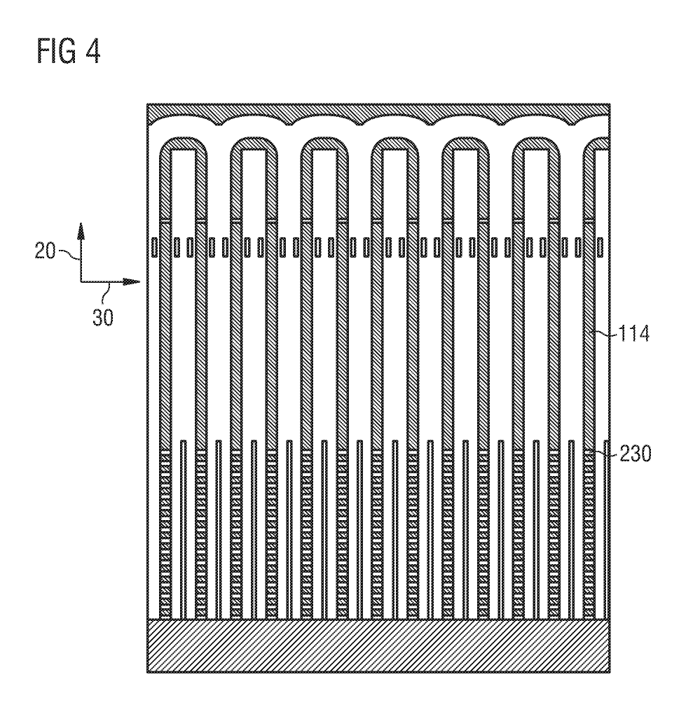

FIG. 4 shows a schematic plan view of a semiconductor substrate having trenches and contact grooves according to further embodiments described herein. FIG. 5 shows a section of the semiconductor substrate of FIG. 4. In the embodiment of FIGS. 4 and 5, the at least one contact groove 230 is segmented along the longitudinal extension of the trenches 120, 121.

Specifically, the semiconductor device includes at least a first trench 120 and a second trench 121 each extending from the source region 113 at least partially into the drift region 115, wherein the first trench 120 and the second trench 121 extend substantially parallel to each other in the first direction 20. The body region 115 is arranged between the first trench 120 and the second trench 121.

The semiconductor device includes at least one contact groove 230 extending from the source region 113, i.e. from the top side 112 of the semiconductor substrate 110, at least partially into the body region 114. The at least one contact groove 230 includes portions having a first extension l3 in the first direction 20 and a second extension w5 in the second direction 30 perpendicular to the first direction 20. In some implementations, the first direction 20 and the second direction 30 are perpendicular to the vertical direction 10. The first direction 20 and the second direction 30 can span a plane perpendicular to the vertical direction 10. Specifically, the plane can be substantially parallel to the surface of the semiconductor substrate 110 provided by the top side 111.

The second extension w5 of the at least one contact groove 230 is larger than the first extension l3. According to some embodiments, the first extension l3 is less than 800 nm, specifically less than 600 nm, and more specifically less than 400 nm. In some implementations, the second extension w5 is in a range of 350 nm to 1200 nm, and specifically in a range of 500 nm to 700 nm. As an example, a ratio of the first extension l3 and the second extension w5 is less than 0.8, specifically less than 0.6, and more specifically less than 0.4.

According to some embodiments, in plane projection onto the top side 112 the semiconductor substrate, a shape of the at least one contact groove 230, and specifically of the segments thereof, is selected from the group consisting of: rectangular, rectangular with rounded edges, stripe-shaped, oval, and any combination thereof.

A distance s1 between a side wall of the first gate trench 120 and a side wall of the at least one contact groove 230 adjacent to the first gate trench 120 and a distance s1 between a side wall of the second gate trench 121 and a side wall of the at least one contact groove adjacent to the second gate trench 121 is less than 400 nm, and specifically less than 300 nm.

The at least one contact groove 230 can have two or more contact grooves, wherein a spacing s3 between two adjacent contact grooves of the two or more contact grooves 230 in the first direction 20 is less than the second extension w5 in the second direction 30. In some embodiments, which can be combined with other embodiments described therein, the spacing s3 is less than 1500 nm, and specifically less than 1000 nm, and more specifically less than 500 nm.

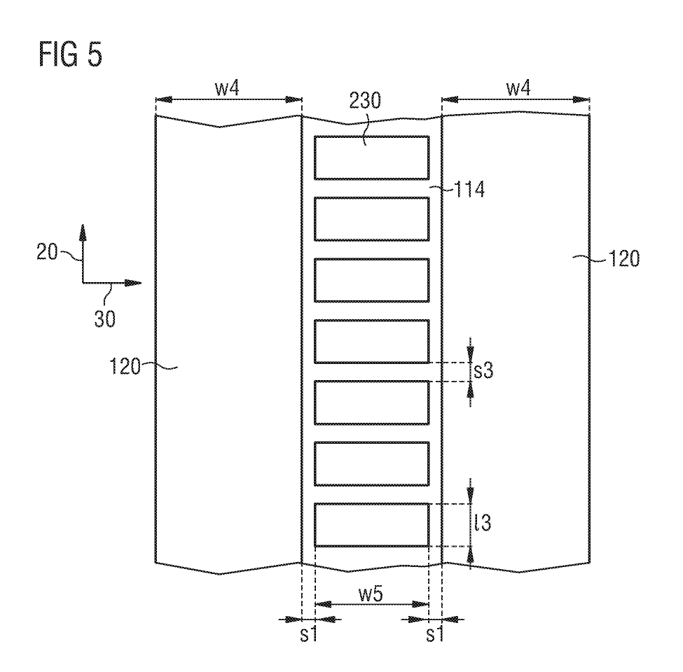

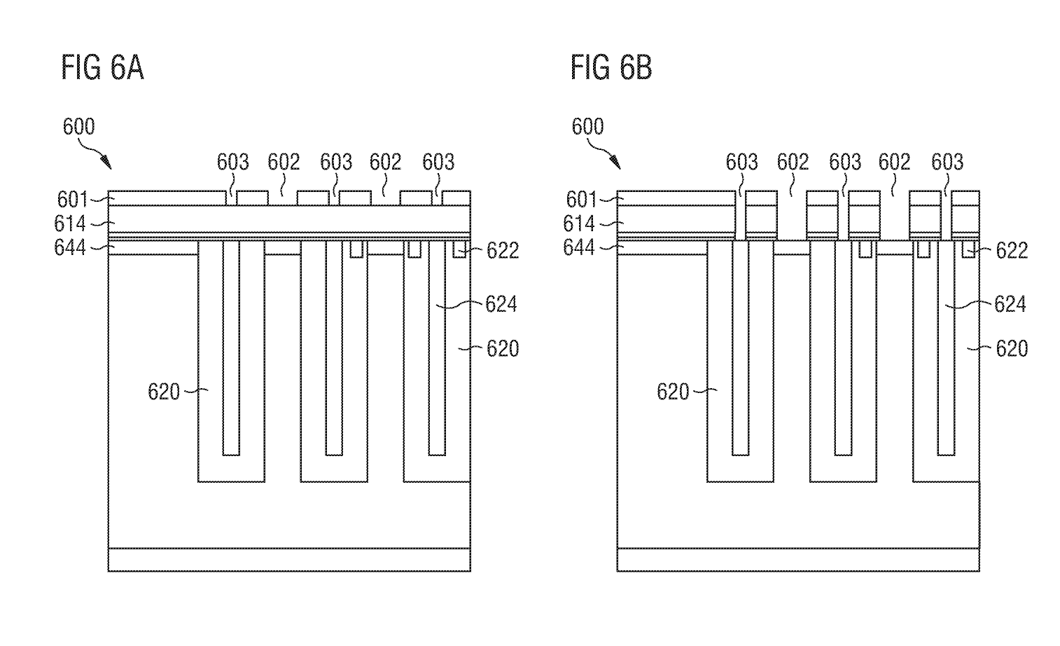

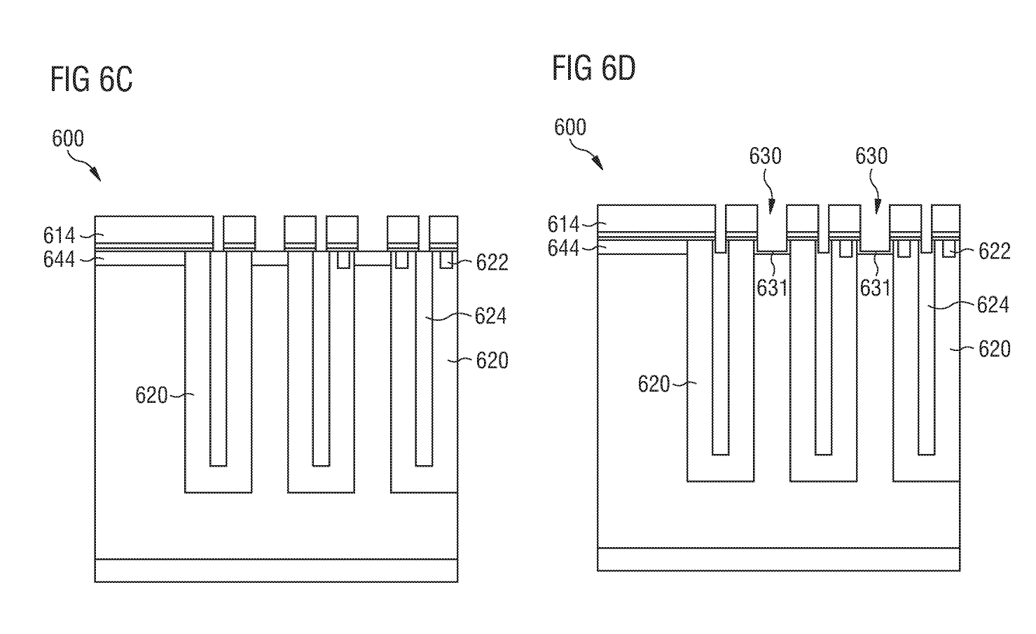

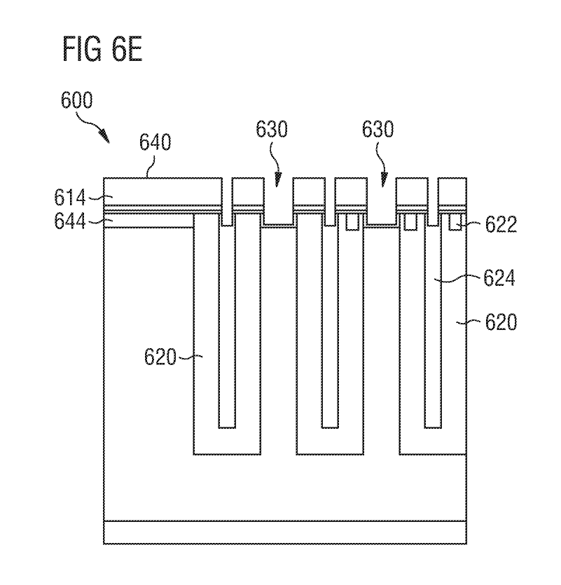

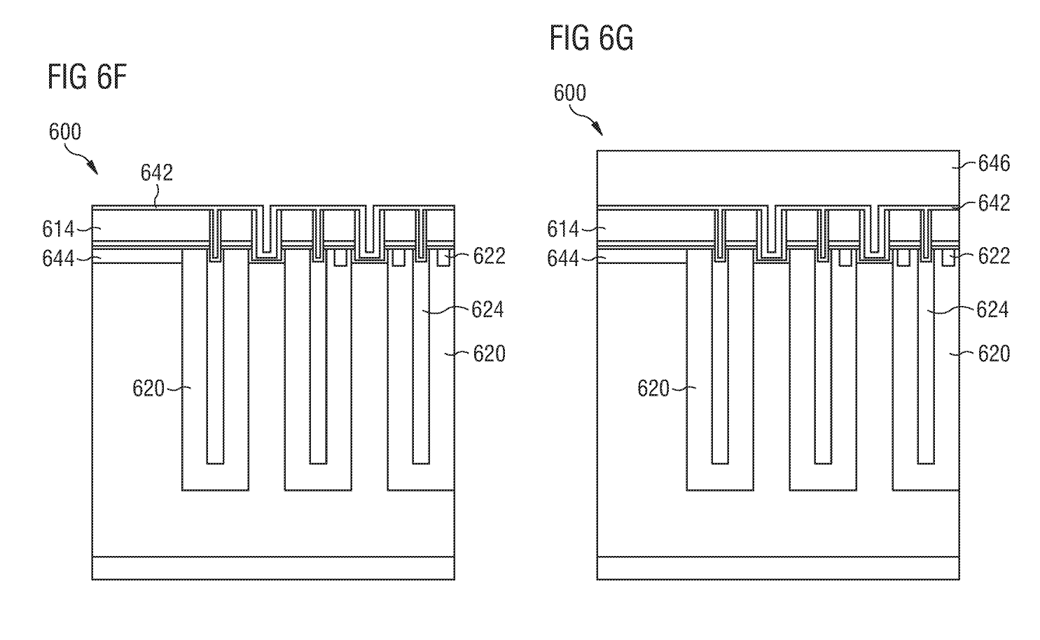

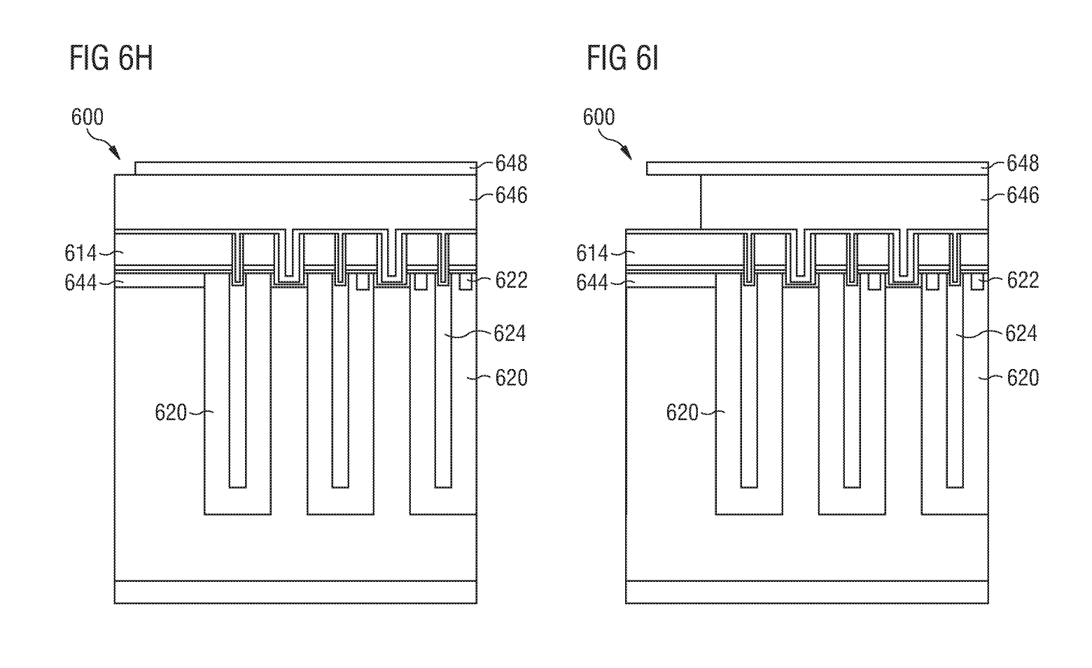

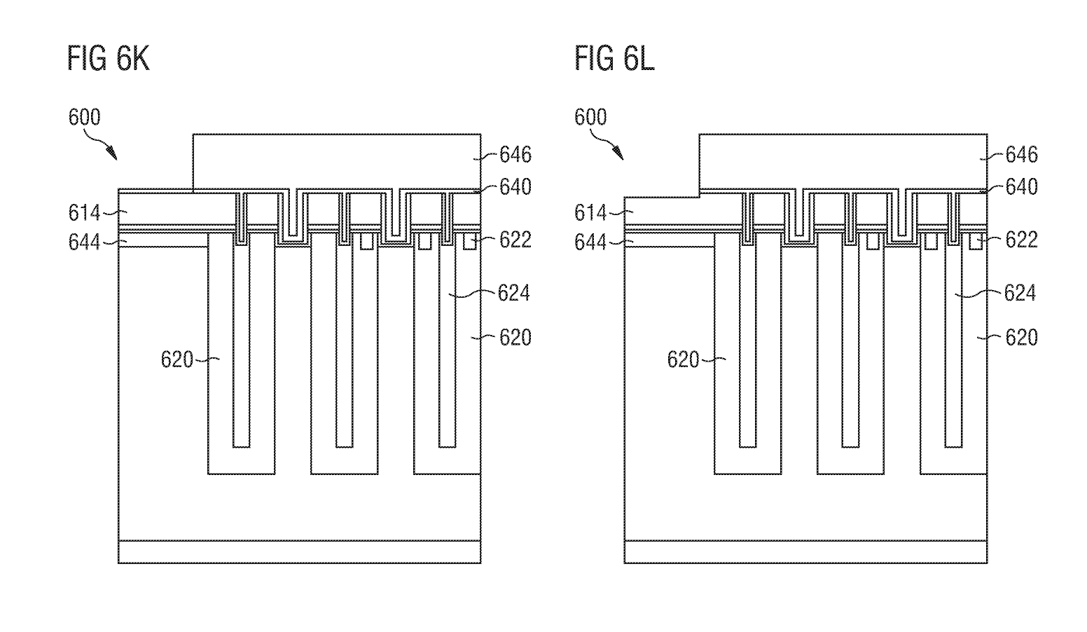

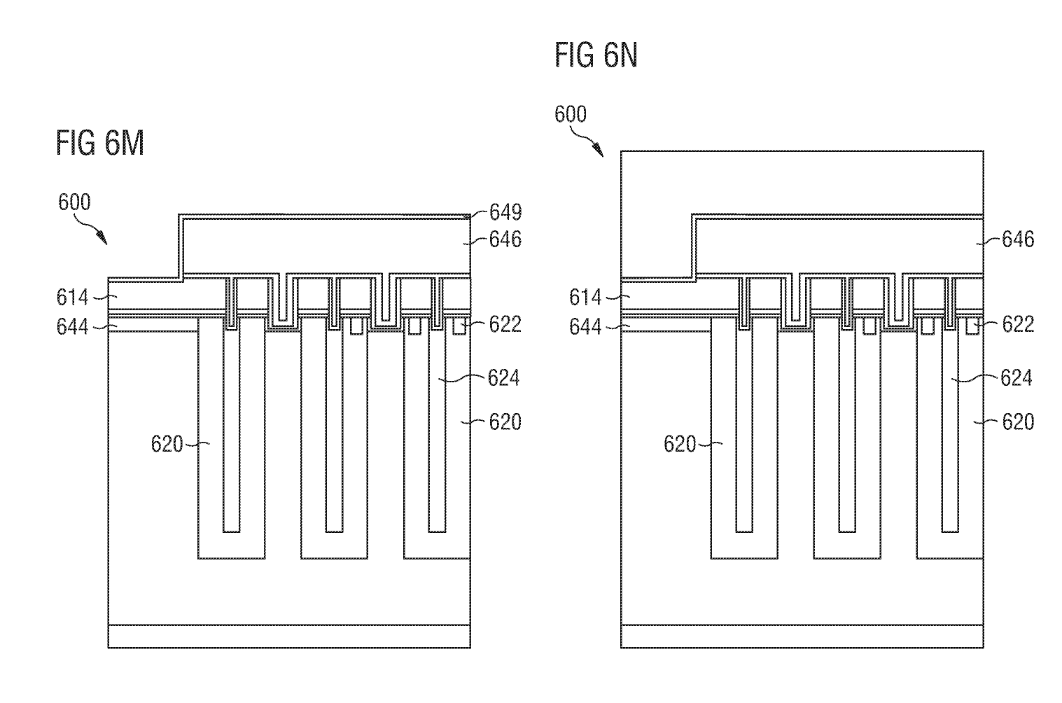

FIGS. 6A to 6I and 6K to 6N show cross-sectional views of the semiconductor device 600 during manufacturing thereof. FIGS. 6A to 6I and 6K to 6N show steps in the manufacture of contact structures of the semiconductor device 600. It is to be understood that various further steps could be conducted before, between and after the steps shown in FIGS. 6A to 6I and 6K to 6N.

Referring to FIG. 6A, trenches 620 are provided, that can accommodate one or more gate electrodes 622 and optionally a field electrode 624. The trenches 620 can be filled with a dielectric material to isolate the gate electrodes 622 and the field electrodes 624 from the semiconductor substrate. A resist 601, such as a photoresist, is provided on top of the semiconductor device 600, for example, an isolating layer 614. The resist 601 can define a plurality of contact structures, such as a first contact structure 602 for defining the contact grooves of the present disclosure. Optionally, the resist 601 can define a second contact structure 603 providing contact trenches for contacting the field electrodes 624.

As shown in FIG. 6B, a first etching step can be performed in order to etch one or more of the underlying layers, for example, the insulating layer 614. The resist 601 can be removed, for example, using plasma or wet removal (FIG. 6C). Anisotropic plasma etching can be conducted to etch the contact groove 630 into the body region 644. A p+ implantation and activation can be performed in order to provide a body contact region 631 at the bottom of the contact groove 630 (FIG. 6D). The body contact region 631 can have a doping concentration higher than a doping concentration of the body region 644.

In the step shown in FIG. 6E, a barrier layer 640 can be deposited. For example, the barrier layer 640 can be made of TiTiN. Rapid thermal processing (annealing) can be performed afterwards. A first metal layer, such as a tungsten layer 642, can be deposited using, for example, chemical vapor deposition (FIG. 6F). As shown in FIG. 6G, a second metal layer 646 can be deposited. The second metal layer 646 can be AlCu. As an example, the second metal layer 646 can be deposited using a physical vapor deposition process, such as a sputtering process. Afterwards, as it is shown in FIG. 6H, a resist layer 648 can be deposited.

As illustrated in FIG. 6I, chemical etching can be performed to etch the first metal layer 642 and the second metal layer 646. Afterwards, the resist layer 648 can be removed, as it is shown in FIG. 6K. Referring to FIG. 6L, the exposed portion of the barrier layer 640 can be etched using a plasma etching process. In FIG. 6M a nitride layer 649 is deposited. In FIG. 6N, an imide 650 is deposited. The imide 650 can provide an encapsulation for the semiconductor device 600.

The embodiments of the present disclosure provide a semiconductor device having a contact groove with a non-linear or segmented configuration allowing for a high avalanche strength while avoiding the occurrence of cavities in the source metal at or near the contact groove due to the increased width of the contact groove.

Spatially relative terms such as “under”, “below”, “lower”, “over”, “upper”, “above” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A semiconductor device, comprising:
a semiconductor substrate comprising, between a bottom side and a top side of the semiconductor substrate and from the top side in a vertical direction, a source region of a first conductivity type, a body region of a second conductivity type, and a drift region of the first conductivity type, wherein the semiconductor substrate further comprises:
a first trench and a second trench extending from the top side at least partially into the drift region, wherein the body region is arranged between the first trench and the second trench; and
a contact groove extending from the top side at least partially into the body region and arranged between the first trench and the second trench, wherein the contact groove has a longitudinal extension in a plane perpendicular to the vertical direction, and wherein the longitudinal extension of the contact groove at least partially has a wave-shape;
a first main electrode arranged on the top side of semiconductor substrate; and
a body contact provided at least partially within the contact groove and configured for contacting at least the first main electrode and the body region.

2. The semiconductor device of claim 1, wherein the wave-shape of the contact groove is selected from the group consisting of: non-linear, meander-shaped, sinusoidal, triangular, rectangular, and any combination thereof.

3. The semiconductor device of claim 1, wherein, in a plane projection onto the top side, the wave-shape of the contact groove is confined within an area defined by a first boundary at a first side of the contact groove and by a second boundary at a second side of the contact groove opposite the first side, and wherein a width of the area in a second direction perpendicular to a longitudinal extension of the first trench and/or the second trench is larger than a width of the contact trench groove.

4. The semiconductor device of claim 3, wherein the width of the area in the second direction is in a range of 350 nm to 1200 nm.

5. The semiconductor device of claim 1, wherein a width of the contact groove is in a range of 200 nm to 700 nm.

6. The semiconductor device of claim 3, wherein a distance between a side wall of the first trench and the first boundary adjacent to the first trench and a distance between a side wall of the second trench and the second boundary adjacent to the second trench is less than 400 nm.

7. A semiconductor device, comprising:
a semiconductor substrate comprising, between a bottom side and a top side of the semiconductor substrate and from the top side in a vertical direction, a source region of a first conductivity type, a body region of a second conductivity type, and a drift region of the first conductivity type, wherein the semiconductor substrate further comprises:
a first trench and a second trench each extending from the top side at least partially into the drift region, wherein the first trench and the second trench extend parallel to each other in a first lateral direction, and wherein the body region is arranged between the first trench and the second trench; and
a contact groove extending from the top side at least partially into the body region, wherein the contact groove comprises portions having a first extension in the first lateral direction and a second extension in a second lateral direction perpendicular to the first lateral direction, wherein the second extension is larger than the first extension;
a first main electrode arranged on the top side of the semiconductor substrate; and
a body contact provided at least partially within the contact groove and configured for contacting at least the first main electrode and the body region.

8. The semiconductor device of claim 7, wherein the first lateral direction and the second lateral direction are perpendicular to the vertical direction.

9. The semiconductor device of claim 7, wherein the first extension is less than 400 nm.

10. The semiconductor device of claim 7, wherein the second extension is in a range of 350 nm to 1200 nm.

11. The semiconductor device of claim 7, wherein a ratio of the first extension and the second extension is less than 0.8.

12. The semiconductor device of claim 7, wherein, in a plane projection onto the top side, a shape of the contact trench is selected from the group consisting of: rectangular, rectangular with rounded edges, stripe-shaped, oval, and any combination thereof.

13. The semiconductor device of claim 7, wherein a distance between a side wall of the first trench and a side wall of the contact groove adjacent to the first trench and a distance between a side wall of the second trench and a side wall of the contact groove adjacent to the second gate trench is less than 400 nm.

14. The semiconductor device of claim 7, wherein the contact groove comprises two or more contact trenches, wherein a spacing between two adjacent contact trenches of the two or more contact trenches in the first lateral direction is less than the second extension in the second lateral direction.

15. The semiconductor device of claim 14, wherein the spacing is less than 1500 nm.

16. The semiconductor device of claim 7, wherein a depth of the contact groove in the vertical direction is less than a depth of the first and second trenches in the vertical direction.

17. The semiconductor device of claim 7, wherein the body contact comprises at least one material selected from the group consisting of: Al, AlCu, W, WTi, TiN, doped polysilicon and any combinations thereof.

18. The semiconductor device of claim 7, wherein the first main electrode is a source electrode or an emitter electrode.

19. A semiconductor device, comprising:
a semiconductor substrate comprising a bottom side and a top side;
a first trench and a second trench each extending from the top side into the semiconductor substrate, wherein the first trench and the second trench extend parallel to each other in a first lateral direction (20);
a semiconductor mesa region arranged between the first trench and the second trench and extending to the top side, the semiconductor mesa region being bound by the first trench and the second trench on opposite sides of the semiconductor mesa region; and
a contact groove formed at the top side of the semiconductor substrate and extending into the semiconductor mesa region, wherein the first trench and the second trench extend from the top side of the semiconductor substrate deeper into the semiconductor substrate than the contact groove,
wherein the contact groove comprises portions having a first extension in the first lateral direction and a second extension in a second lateral direction perpendicular to the first lateral direction, wherein the second extension is larger than the first extension.

20. The semiconductor device of claim 19, wherein the semiconductor device is a metal-oxide-semiconductor field-effect transistor (MOSFET) or an insulated-gate bipolar transistor (IGBT).
